(19) United States
(12) Patent Application Publication
(10) Pub. No.: US 2022/0267887 A1
(43) Pub. Date: Aug. 25, 2022

(54) COATING FOR THE SURFACE OF AN ARTICLE AND PROCESS FOR FORMING THE COATING

(71) Applicant: Teer Coatings Limited, Droitwich Worcestershire (GB)

(72) Inventors: Hailin Sun, Droitwich Worcestershire (GB); Parnia Navabpour, Droitwich Worcestershire (GB)

(73) Assignee: Teer Coatings Limited, Droitwich Worcestershire (GB)

(21) Appl. No.: 17/628,157

(22) PCT Filed: Jul. 22, 2020
(86) PCT No.: PCT/GB2020/051741

§ 371 Date: Jan. 18, 2022

(30) Foreign Application Priority Data
Jul. 22, 2019 (GB) 1910455.3

(51) Int. Cl. C23C 14/04; C23C 14/06; C23C 14/08; C23C 14/14; C23C 14/16; C23C 14/35; H01M 8/0206; H01M 8/021; H01M 8/0228

(52) U.S. Cl. CPC C23C 14/04; C23C 14/0641; C23C 14/083; C23C 14/0605; C23C 14/14; C23C 14/16; C23C 14/35; H01M 8/0206; H01M 8/021; H01M 8/0228

(57) ABSTRACT

The invention to which this application relates is for the formation of a coating onto a surface of an article and, in particular, although not necessarily exclusively, to form a coating which has conductive characteristics in order for the purpose of use of the article to be achieved. In one embodiment, the article base to which the coating is applied is a fuel cell or plate for a fuel cell. The coating includes at least one layer and an external layer applied thereto, said external layer provide as a discontinuous layer formed of discrete portions. The invention also relates to the method of application of a coating having the required characteristics.

The invention to which this application relates is for the formation of a coating onto a surface of an article and, in particular, although not necessarily exclusively, to an article which requires the coating to be conductive in order for the purpose of the article to be achieved. In one embodiment, the article can be a fuel cell or plate for a fuel cell. The invention also relates to the method of application of a coating having the required characteristics.

Articles which are required to have a conductive characteristic, are well-known and one form of article is a fuel cell, electrode or bipolar, plate which can be used, in conjunction with other electrodes or bipolar plates as part of a power generation system which may, for example, be utilised in a vehicle to allow the propulsion of the vehicle in addition to or instead of other power sources. It is found that in practice, the base or core of the article, which is typically formed of a conductive material, is subject to corrosion and subsequent loss of performance or even failure due to the fluids or gases in which the article is placed during the operation of the same. As a result of the adverse effect of the corrosion on the performance of the article, there is a need to be able to protect the core or base of the article from the corrosive medium in order to prolong the life of the article.

One known means for achieving this, is to provide the article with a coating which forms the external surface of the article when the same is provided for use and to form the external surface of the coating of a material which is known to be resistant to corrosion whilst, at the same time, allowing the conductive effect which is required to be present at the external surface of the article to be replicated by the coating.

One method by which this is achieved, is to apply a continuous coating of a noble metal such as gold but the use of this form of material is expensive and, as a result, the provision of a continuous coating of gold of a sufficient depth to ensure that the coating has the required conductive characteristics, is prohibitively expensive or, if the coating is applied so as to have a reduced depth then while this may reduce the expense of the same, it is found that the conductive or corrosion resistant characteristics which are required for operation of the article, are not achieved. In addition, the bonding of the conductive coating to the substrate my not be sufficient which can result in the removal of the same and subsequently corrosion and loss of conductivity.

Thus there have been several different attempts made to overcome the known problems but, to date, it is believed that these have not been entirely successful.

An aim of the present invention is therefore to provide a coating for an article and for the article with the coating applied thereto, and a method of applying the coating which achieves the required resistance to corrosion so as to ensure that the life of the article renders the same economically attractive whilst, at the same time, ensuring that the ability for the article to achieve the required aims, in terms of conductivity, performance and efficiency.

In a first aspect of the invention, there is provided an article, said article including a base and onto at least part of the surface thereof there is applied a coating, said coating including a layer of a corrosion resistant material and onto which an external layer is applied which has conductive characteristics and wherein said external layer is formed as a non-continuous layer in the form of discrete areas.

In one embodiment the said external layer covers less than all of the surface of the layer of the coating onto which the same is applied.

In one embodiment, the said external layer is applied so that portions of the layer of the coating onto which the said external layer is applied, are exposed at locations of the external surface of the coating.

In one embodiment, the said portions are randomly positioned across the external surface of the coating.

In one embodiment, the external layer is applied in a manner so as to form an interconnected mesh like external layer of the coating.

In one embodiment the said external layer has a depth in the range of 2-30 nanometres.

In one embodiment, the corrosion resistant layer is formed by a plurality of sublayers and at least one sub-layer includes any, or any combination, of an oxide or a nitride of titanium, zirconium, niobium, carbon and/or graphene.

In one embodiment said sub-layer is positioned to underlie the said external layer.

In one embodiment, the said corrosion resistant layer has a depth in the range of 10-70 nanometres.

In one embodiment the said corrosion resistant layer is produced by the application, in sequence, of two or more of a sub-layer of titanium, a sub-layer of titanium oxide or titanium nitride and a sub-layer of titanium applied thereon.

In one embodiment, the corrosion resistant layer includes an oxide or a nitride of a metal which is used as part of said layer.

In one embodiment, the external layer is applied to a depth of 2-30 nanometres and is formed of any of carbon, gold, another precious metal, or noble metal such as platinum or ruthenium and/or graphite.

In one embodiment, the coating includes a further layer which is applied to the surface of the article and said further layer is formed by any or any combination of titanium, zirconium, niobium or hafnium.

In one embodiment, the article is formed of any titanium, stainless steel, aluminium alloy or aluminium.

In one embodiment, the coating includes conductive paths from the external layer where present to the corrosion resistant layer and hence to the article. In those portions where there is no external layer applied then there may be no conductive path to the article and therefore the external layer is applied to the corrosion resistant layer to a sufficient extent so as to provide coverage of the corrosion resistant layer so as to provide the required conductive characteristics for the operation of the article once the coating has been applied thereto.

In a further aspect of the invention there is provided a coating for an article, the said coating including a layer formed of any or any combination of titanium, zirconium, niobium and/or hafnium, a corrosion resistant layer including an oxide or nitride of titanium, zirconium, niobium, carbon, graphene or any combination thereof and an external layer formed of gold, another precious metal, or noble metal or graphite and wherein the external layer is a non-continuous layer formed by discrete portions on said corrosion resistant layer.

In a further aspect of the invention, there is provided a method of forming a coating on the surface of an article, said method comprising the steps of sputter depositing a corrosion resistant layer including a metal or alloy and/or an oxide or nitride of a metal or alloy selected from titanium, zirconium, niobium, hafnium or a carbon material using appropriate targets of said selected materials which are sputter deposited from magnetrons into a chamber in which the said articles are located and moved, either linearly or rotatably, and wherein an electrically conductive external layer is applied to the said corrosion resistant layer and wherein said external layer is applied so as to form a non-continuous layer so as to allow portions of the corrosion resistant layer to be exposed at the external surface of the coating of the article.

Typically, the said external layer is applied to a sufficient extent to the corrosion resistant layer so as to allow conductive paths to be formed between the external layer and the article so as to allow the required conductance characteristics for the article to be provided.

In one embodiment, the method includes the initial step of ion cleaning the surface of the article to which the coating is to be applied.

In one embodiment, a heating step is undertaken on the coating once the same has been applied to the article. The heating step aids the formation of a network of corrosion protection metal oxide with the noble metal and/or carbon providing the conductive path.

In one embodiment, the heating step is performed prior to the unloading of the articles from the coating apparatus.

In one embodiment the external layer includes gold, another precious metal, a noble metal and/or graphite.

In one embodiment the said external layer is applied using sputter deposition of material from the appropriate material targets from magnetrons into a chamber in which the said articles are located and moved, either linearly or rotatably.

In one embodiment the method includes the step of applying a further layer which is applied to the surface of the article and said further layer is formed by any or any combination of titanium, zirconium, niobium or hafnium and then applying the said corrosion resistant layer thereto.

Specific embodiments of the invention are now described with reference to the accompanying Figures; wherein.

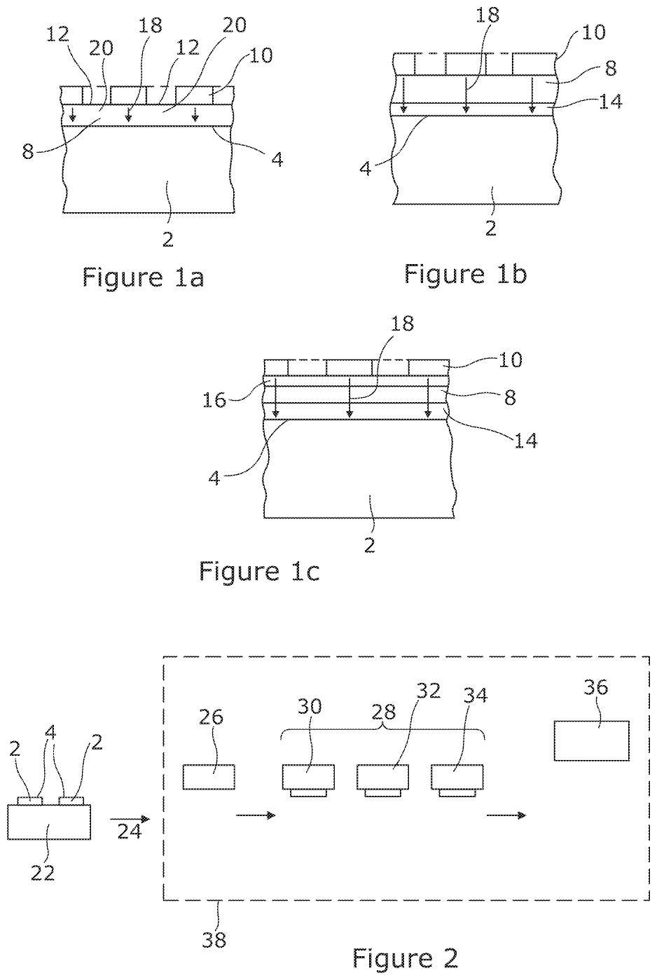

FIGS. 1a-e illustrate embodiments of the coating in accordance with the invention; and

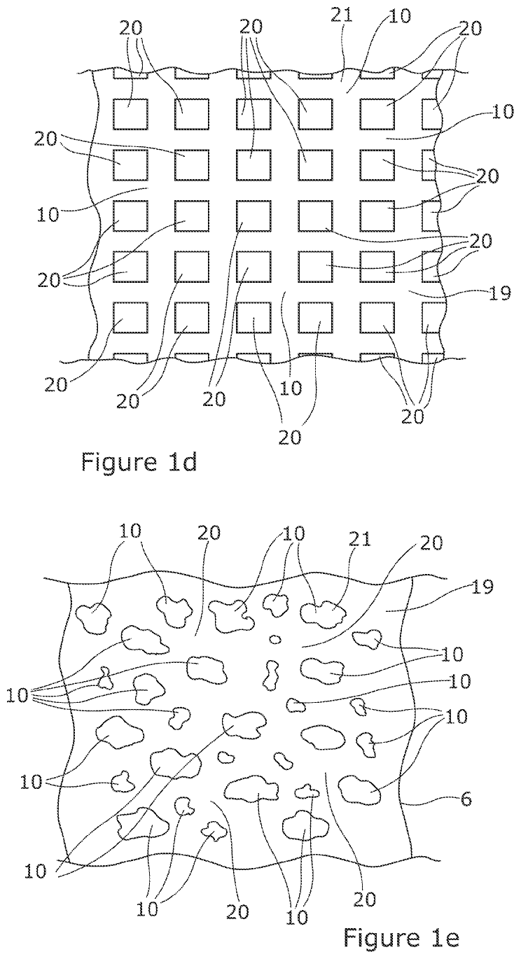

FIG. 2 illustrates one embodiment of apparatus which may be used to perform the method steps for application of the coating in accordance with one embodiment.

Referring firstly to FIGS. 1a-c, there are illustrated elevations of three embodiments of a coating formed in accordance with the invention and in FIG. 1d there is formed a plan view of one embodiment of the coating. In each of the embodiments, there is provided an article 2 which has a surface 4 to which the coating is applied.

Although only part of the article is shown, it should be appreciated that the coating which is applied may be applied to the entire article or to a portion thereof depending on the particular characteristics which are required.

The article 2 is typically formed of a conductive material such as, for example, titanium, stainless steel, aluminium alloy or aluminium and may in one embodiment be a plate for a fuel cell.

In the embodiment as shown in FIG. 1a, the article 2 has a coating 6 applied thereto which includes a layer 8 with corrosion resistance characteristics. In this embodiment the layer 8 is applied to the surface 4 of the article and then, applied thereon, is a conductive, external layer 10 which, as shown in an exaggerated manner, is formed as a non-continuous layer manner by the formation of discrete areas, so that portions 12 of the corrosion resistant layer are exposed between said areas at the external surface of the coating so as to form part of the external surface of the coating. The conductive external layer 10, is in this embodiment, formed of gold and the corrosion resistant layer 8 is formed of a titanium oxide or a titanium nitrite.

The pattern of application of said external layer 10 areas may be a random pattern as illustrated in FIG. 1e which shows a plan view of the external surface 19 of the coating 6 formed by areas 21 or may be a predetermined pattern of areas 21 such as, for example, to form an interconnected mesh pattern external coating, as shown in FIG. 1d which shows the plan view of this embodiment of the coating, and in both embodiments portions 20 of the corrosion resistant layer 8 are exposed at the external surface 19.

In FIG. 1b, there is illustrated a further embodiment in which there is again provided the non-continuous external, conductive layer 10 and in this embodiment there is provided a further layer of titanium 14 which is first applied to the surface 4 of the article 2 and then the corrosion resistant layer 8 including titanium oxide or titanium nitride is applied thereon.

In FIG. 1c, there is illustrated that the corrosion resistant layer 8 is formed of a series of sub-layers so that in this embodiment the coating comprises the further layer 14, a sub layer 8 of metal oxide or metal nitride and then a sub-layer of metal such as titanium 16 is provided prior to the application of the conductive external layer 10. It is likely that the sub-layer 16 will be required if the sub-layer 8 underlying the same is formed of a metal nitride.

The external layer 10, can be selected and applied so as to have a specific coverage of the surface of the underlying layer so that the extent of coverage of the underlying layer by the external layer can be selected to allow the particular conductive characteristics of the article when the coating has been applied thereto, to be selected.

As already stated, FIG. 1d illustrates a plan view of one form of the external layer 10 having an interconnected mesh like pattern of areas 21 and FIG. 1e illustrates the external coating formed by a series of randomly positioned areas 21.

It is believed that in accordance with the invention, conductive paths are formed from the external layer areas, where applied, and pass through the corrosion resistant layer 8 as indicated by arrows 18 in FIGS. 1a-c to reach the article base 2 which is formed of a conductive material and thereby allow the required conductive characteristics of the article for effective operation to be achieved with the coating having been applied thereto whilst, at the same time, the provision of the corrosion resistance layers allow the corrosion of the article to be reduced. In those portions 20 of the corrosion resistant layer 8 which are not covered by the external layer 10, it is believed that additional oxidation of the material may occur upon exposure to normal operating conditions but this has no significant impact on the performance of the article as there is still sufficient protection given by the discrete are as of the external layer which have been applied.

Referring now to FIG. 2, there is illustrated a linear sputter coating apparatus and method which can be used to apply the said coating, in accordance with one embodiment of the invention. In this embodiment there is provided a holder 22 on which one or a series of articles 2 which are to be coated are located. The holder 22 moves in a linear direction as indicated by arrow 24 unto a coating chamber 38 shown in broken lines, and at a first stage 26 in the chamber, in which a vacuum may be created, there is performed an ion cleaning step which allows the surface 4 of the articles 2 onto which the coating is to be applied, to be cleaned.

The holder then moves to a coating stage 28 at which appropriate targets of material are positioned on unbalanced magnetrons 30, 32, 34 so as to allow the selective operation of the magnetrons and allow the sputter deposition of the particular materials which are to form the layers of the coating as described with regard to FIGS. 1a-c, and in a particular required sequence of operation and for selected periods of time so as to form the coating layers to predetermined depths. Once the layers of the coating have been applied to form the coating, the holder 22 and coated articles 2 thereon, are moved to a heating stage 36 at which the articles and the applied coatings are heated to a predetermined temperature, typically in the range of 50-300 Celsius, to further condition the coating and then the articles can be removed from the apparatus and provided for use.

The current invention therefor allows a corrosion resistant layer to be applied to an article to protect the same from corrosion whilst eliminating the formation of pinholes and, at the same time, avoiding the need for gold or another noble or precious metal to have to be provided in the corrosion protection layer, whilst also ensuring that it is possible to obtain excellent conductivity characteristics of the coating without the inclusion of gold in the internal/intermediate layers of the coating.

1. An article, said article comprising:
a base and onto at least part of the surface thereof there is applied a coating, said coating including a corrosion resistant layer and onto which an external layer is applied which has conductive characteristics and wherein said external layer is formed as a non-continuous layer in the form of discrete areas.

2. An article according to claim 1 wherein the said external layer is applied such that portions of the said corrosion resistant layer are exposed at locations of the external surface of the coating.

3. An article according to claim 2 wherein said portions are randomly positioned across the external surface of the coating.

4. An article according to claim 1 wherein the external layer forms an interconnected mesh layer.

5. An article according to claim 1 wherein the said corrosion resistant layer has a depth in the range of 10-70 nanometres and the said external layer has a depth in the range of 2-30 nanometres.

6. An article according to claim 1 wherein the said corrosion resistant layer is formed by a plurality of sublayers and at least one sub-layer includes any, or any combination, of an oxide of titanium, zirconium, niobium, carbon or graphene.

7. An article according to claim 6 wherein the said corrosion resistant layer includes an oxide or a nitride of a material which is provided as part of said layer.

8. An article according to claim 6 wherein the said corrosion resistant layer includes, in order from the article, a sub-layer of titanium applied onto the surface of the article, a sub-layer of titanium oxide or titanium nitride and a further sub-layer of titanium

9. (canceled)

10. An article according to claim 1 wherein the said external layer includes gold, another precious metal, a noble metal and/or graphite.

11. (canceled)

12. An article according to claim 1 wherein the coating includes a further layer formed by any, or any combination, of titanium, zirconium, niobium or hafnium.

13. An article according to claim 12 wherein, in order from the article surface, the coating includes said further layer, the corrosion resistant layer and the external layer.

14. An article according to claim 1 wherein the article base is formed of any of titanium, stainless steel, aluminium alloy or aluminium.

15. An article according to claim 1 wherein conductive paths are formed from the external layer to the corrosion resistant layer and article base.

16. An article according to claim 1 wherein the base is a bipolar plate for use as part of a fuel cell.

17. An article according to claim 1 wherein the said coating has an Interfacial Contact Resistance (ICR) of <15 mΩcm², and preferably <5 mΩcm².

18. An electrically conductive coating for an article, said coating comprising:
a layer formed of any or any combination of titanium, zirconium, niobium and/or hafnium, a corrosion resistant layer including an oxide or nitride of titanium, zirconium, niobium, carbon, graphene or any combination thereof and an external layer formed of gold, another precious metal, or noble metal or graphite and wherein the external layer is a non-continuous layer formed by discrete portions on said corrosion resistant layer.

19. A coating according to claim 18 wherein portions of the said corrosion resistant layer are exposed at the external surface of the coating.

20. (canceled)

21. A bipolar plate for a fuel cell coated with a coating in accordance with claim 18.

22. A method of forming a coating on the surface of an article, said method comprising the steps of:
sputter depositing a corrosion resistant layer including a metal or alloy and/or an oxide or nitride of a metal or alloy selected from titanium, zirconium, niobium, hafnium or a carbon material using appropriate targets of said selected materials which are sputter deposited from magnetrons into a chamber in which the said articles are located and moved, either linearly or rotatably, and wherein an electrically conductive external layer is applied to the said corrosion resistant layer and wherein said external layer is applied so as to form a non-continuous layer so as to allow portions of the corrosion resistant layer to be exposed at the external surface of the coating of the article.

23. A method according to claim 22 wherein the method includes the initial step of ion cleaning the surface of the article to which the coating is to be applied.

24. A method according to claim 21 wherein a heating step is undertaken on the coating once the same has been applied to the article.

25. (canceled)

26. A method according to claim 22 wherein the external layer includes gold, another precious metal, a noble metal and/or graphite.

27. A method according to claim 22 wherein the said external layer is applied using sputter deposition of material from the appropriate material targets from magnetrons into a chamber in which the said articles are located and moved, either linearly or rotatably.

28. A method according to claim 22 wherein the method includes the step of applying a further layer which is applied to the surface of the article and said further layer is formed by any or any combination of titanium, zirconium, niobium or hafnium and then applying the said corrosion resistant layer thereto.
